(19) United States
(12) Patent Application Publication
(10) Pub. No.: US 2023/0201887 A1
(43) Pub. Date: Jun. 29, 2023

(54) SUBSTRATE CLEANING DEVICE AND SUBSTRATE CLEANING METHOD

(71) Applicant: Samsung Electronics Co., Ltd., Suwon-si (KR)

(72) Inventors: Yunjin Kim, Hwaseong-si (KR); Kiho Bae, Seoul (KR); Boun Yoon, Seoul (KR); Ilyoung Yoon, Hwaseong-si (KR)

(21) Appl. No.: 17/947,242

(22) Filed: Sep. 19, 2022

(30) Foreign Application Priority Data
Dec. 29, 2021 (KR) 10-2021-0191086

(51) Int. Cl. B08B 3/12; B08B 1/04; B08B 3/08

(52) U.S. Cl. CPC B08B 3/12; B08B 1/04; B08B 3/08

(57) ABSTRACT

A substrate cleaning device, includes: a substrate cleaning module including first and second roll members adjacent to lower and upper surfaces of a substrate, respectively, first and second driving units configured to move the first and second roll members, a first roll cleaning module including a roll receiving region, a first cleaning solution supply unit supplying a first cleaning solution, and an ultrasonic generating unit applying ultrasonic vibrations; a second roll cleaning module including a housing, a brush pad in the housing, and a second cleaning solution supply unit supplying a second cleaning solution; and a control unit controlling the first driving unit so that the first roll member contacts the substrate lower surface or is accommodated in the roll receiving region, and to control the second driving unit so that the second roll member contacts the substrate upper surface or is seated on the brush pad.

### CROSS-REFERENCE TO RELATED APPLICATION

This application claims the priority and benefit under 35 U.S.C. § 119 of Korean Patent Application No. 10-2021-0191086, filed on Dec. 29, 2021, with the Korean Intellectual Property Office, the entire disclosure of which is incorporated herein by reference.

### BACKGROUND

### 1. Field

The present inventive concept relates to a substrate cleaning device and a substrate cleaning method.

### 2. Description of Related Art

In order to form microstructures (e.g., a metal film, a barrier film, an insulating film, or the like) on a substrate (e.g., a semiconductor wafer), a planarization process of polishing and cleaning a surface of the substrate using a substrate processing device is accompanied. Abrasive residues (e.g., slurry residues, abrasive debris, or the like) are present in a roll member for scrub cleaning a surface of the polished substrate, which may cause deterioration of a cleaning effect.

### SUMMARY

An aspect of the present inventive concept is to provide a substrate cleaning device having improved cleaning ability and a substrate cleaning method.

According to an aspect of the present inventive concept, a substrate cleaning device, includes: a substrate cleaning module including a first roll member disposed adjacent to a lower surface of a substrate, a first driving unit configured to move the first roll member in vertical and horizontal directions with respect to the lower surface of the substrate, a second roll member disposed adjacent to an upper surface of the substrate, and a second driving unit configured to move the second roll member in vertical and horizontal directions with respect to the upper surface of the substrate; a first roll cleaning module including a processing tank including a roll receiving region having the first roll member accommodated therein, a first cleaning solution supply unit configured to supply a first cleaning solution to the roll receiving region, and an ultrasonic generating unit configured to apply ultrasonic vibrations to the first cleaning solution supplied to the roll receiving region; a second roll cleaning module including a housing having the second roll member accommodated therein, a brush pad disposed in the housing and on which the second roll member is seated, and a second cleaning solution supply unit configured to supply a second cleaning solution to the brush pad on which the second roll member is seated; and a control unit configured to control the first driving unit so that the first roll member is in contact with the lower surface of the substrate or is accommodated in the roll receiving region of the processing tank, and to control the second driving unit so that the second roll member is in contact with the upper surface of the substrate or is seated on the brush pad in the housing.

According to an aspect of the present inventive concept, a substrate cleaning device, includes: a substrate cleaning module including a first roll member disposed adjacent to a lower surface of a substrate, a first driving unit configured to move the first roll member in vertical and horizontal directions with respect to the lower surface of the substrate, a second roll member disposed adjacent to an upper surface of the substrate, and a second driving unit configured to move the second roll member in vertical and horizontal directions with respect to the upper surface of the substrate; a roll cleaning module including a processing tank including a roll receiving region having the first roll member or the second roll member accommodated therein, a cleaning solution supply unit configured to supply a cleaning solution to the roll receiving region, and an ultrasonic generating unit configured to apply ultrasonic vibrations to the cleaning solution supplied to the roll receiving region; and a control unit configured to control the first and second driving units so that the first roll member and the second roll member are in contact with the lower surface and the upper surface of the substrate, respectively, or are accommodated in the roll receiving region of the processing tank.

According to an aspect of the present inventive concept, a substrate cleaning device includes: a substrate cleaning module including a first roll member having first protrusions, and disposed adjacent to a lower surface of a substrate, a first driving unit configured to move the first roll member in vertical and horizontal directions with respect to the lower surface of the substrate, and a second roll member having second protrusions and disposed adjacent to an upper surface of the substrate, and a second driving unit configured to move the second roll member in vertical and horizontal directions with respect to the upper surface of the substrate; a first roll cleaning module including a processing tank including a roll receiving region having the first roll member accommodated therein, a first cleaning solution supply unit configured to supply a first cleaning solution to the roll receiving region, and an ultrasonic generating unit configured to apply ultrasonic vibrations to the first cleaning solution supplied to the roll receiving region; a control unit configured to control the first driving unit so that the first roll member is in contact with the lower surface of the substrate or is accommodated in the roll receiving region of the processing tank, wherein, when each of the first roll member and the second roll member is in contact with the lower surface and the upper surface of the substrate, at least a portion of the first protrusions and at least a portion of the second protrusions are in contact with each other.

According to an aspect of the present inventive concept, a substrate cleaning method includes operations of: preparing a substrate having an upper surface to which a polishing process is applied and a lower surface opposite to the upper surface; fixing the substrate above a spindle and rotating the same horizontally; contacting a first roll member and a second roll member to the lower surface and the upper surface of the substrate, respectively; scrub cleaning the lower surface and the upper surface of the substrate by rotating the first roll member and the second roll member; immersing the first roll member in a cleaning solution in a processing tank, and applying ultrasonic vibrations to the cleaning solution; and seating the second roll member on a brush pad of a housing, and rotating the second roll member.

### BRIEF DESCRIPTION OF DRAWINGS

The above and other aspects, features, and advantages of the present inventive concept will be more clearly understood from the following detailed description taken in conjunction with the accompanying drawings, in which:

FIG. 1 is a diagram schematically illustrating a configuration of a substrate cleaning device, according to an example embodiment of the present inventive concept;

FIGS. 2A to 2G are views illustrating a process of cleaning the first roll member of FIG. 1, according to an example embodiment of the present inventive concept;

FIG. 3 is a diagram schematically illustrating a configuration of a substrate cleaning device, according to an example embodiment of the present inventive concept;

FIG. 4 is a view illustrating a process of cleaning the second roll member of FIG. 3, according to an example embodiment of the present inventive concept;

FIG. 5 is a diagram illustrating an example of a substrate processing device to which the substrate cleaning device, according to an example embodiment of the present inventive concept, is introduced;

FIG. 6A is a perspective view schematically illustrating a use state of a substrate cleaning module of a substrate cleaning device provided in the substrate processing device of FIG. 5; and

FIG. 6B is a partially enlarged view illustrating region ‘C’ of FIG. 6A.

### DETAILED DESCRIPTION

Hereinafter, preferred example embodiments of the present inventive concept will be described with reference to the accompanying drawings as follows. Like numbers refer to like elements throughout.

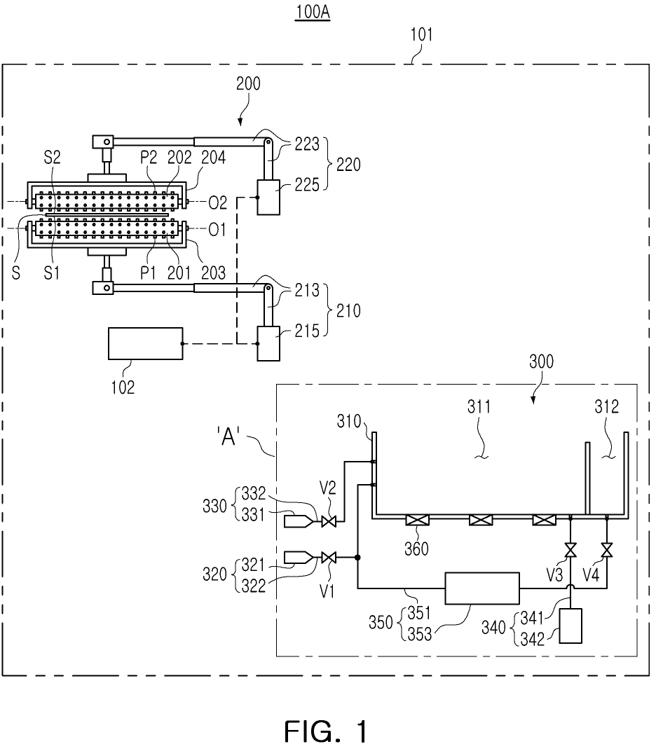

FIG. 1 is a diagram schematically illustrating a configuration of a substrate cleaning device 100A according to an example embodiment of the present inventive concept.

Referring to FIG. 1, a substrate cleaning device 100A according to an example embodiment may include a substrate cleaning module 200 and a roll cleaning module (or a ‘first roll cleaning module’) 300. The substrate cleaning module 200 and the roll cleaning module 300 may be disposed in one space, for example, a processing chamber 101.

In the present inventive concept, by introducing a roll cleaning module 300 for removing particles (e.g., slurry residues, abrasive debris, or the like) attached to the first roll member 201 and/or the second roll member 202 of the substrate cleaning module 200, reverse contamination between the first roll member 201 and the second roll member 202 may be prevented, and cleaning efficiency of the substrate cleaning module 200 may be improved. For example, in the substrate cleaning device 100A of the present example embodiment, the first roll member 201 and the second roll member 202 may be in contact with lower and upper surfaces of a substrate S, respectively, to scrub the substrate S, and the substrate cleaning device 100A may include a control unit 102 for moving the first roll member 201 and the second roll member 202 into a processing tank 310 of the roll cleaning module 300.

The substrate cleaning module 200 may include a first roll member 201, a first driving unit 210, a second roll member 202, and a second driving unit 220.

The first roll member 201 may be disposed adjacent to a lower surface S1 of the substrate S, and the second roll member 202 may be disposed adjacent to an upper surface S2 of the substrate S. The first and second roll members 201 and 202 may extend parallel to the lower surface S1 and the upper surface S2 of the substrate S, respectively, and may have a length greater than a diameter of the substrate S. Each of the first and second roll members 201 and 202 may have a cylindrical shape having first and second protrusions P1 and P2 on their outer peripheral surfaces, respectively. The first and second roll members 201 and 202 may be formed of, for example, a polymer such as polyvinyl alcohol (PVA).

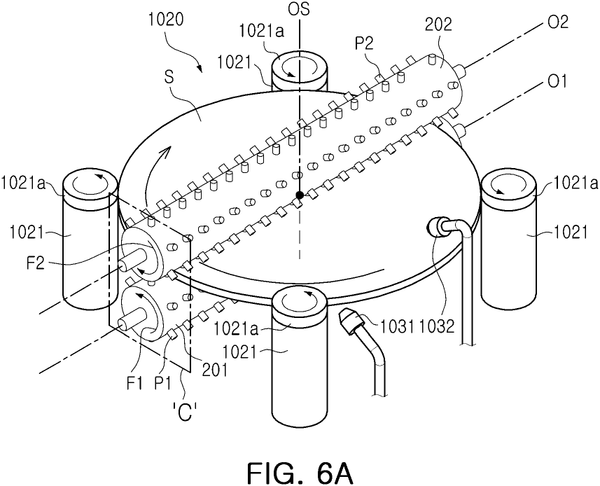

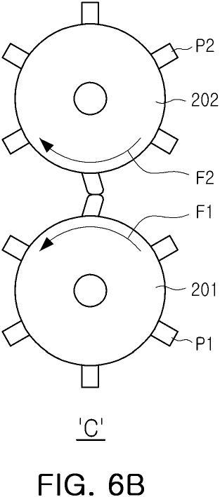

The first and second roll members 201 and 202 may be rotatably installed in close contact with the lower surface S1 and the upper surface S2 of the substrate S, respectively. For example, the substrate cleaning module 200 may further include a first roll holder 203 configured to rotate the first roll member 201 and a second roll holder 204 configured to rotate the second roll member 202. In this case, a first rotation shaft O1 of the first roll member 201 may be parallel to the lower surface S1 of the substrate S, and a second rotation shaft 02 of the second roll member 202 may be parallel to an upper surface S2 of the substrate S. As the first and second roll members 201 and 202 rotate, first and second protrusions P1 and P2 may be in contact with the lower surface S1 and the upper surface S2 of the substrate S, and the substrate S may be scrub cleaned. Meanwhile, the substrate S may be rotated horizontally by one or more spindles (see, e.g., spindles 1021 in FIG. 6A), which will be described later with reference to FIG. 6A.

The first and second driving units 210 and 220 may be configured to move the first and second roll members 201 and 202 in a vertical direction (e.g., a direction perpendicular to the lower and upper surfaces S1 and S2 of the substrate S) and a horizontal direction (e.g., a direction parallel to the lower and upper surfaces S1 and S2 of the substrate S) on the lower surface S1 and the upper surface S2 of the substrate S, respectively. For example, each of the first and second driving units 210 and 220 may include at least one of robot arms 213 and 223 and at least one of driving members 215 and 225 transmitting driving force to the at least one of robot arms 213 and 223. For example, the first driving member 215 may apply driving force to the first robot arm 213 so that the first roll member 201 is raised below the substrate S to bring the first roll member 201 closer to the substate S. The second driving member 225 may apply driving force to the second robot arm 223 so that the second roll member 202 is lowered from above the substrate S to bring the second roll member 202 closer to the substate S. Each of the first and second driving members 215 and 225 may include a hydraulic actuator, a magnetic actuator, a mechanical actuator, or the like.

The roll cleaning module 300 may include a processing tank 310, a cleaning solution supply unit 320, a rinsing solution supply unit 330, a discharge unit 340, a circulation unit 350, and an ultrasonic generating unit 360.

The processing tank 310 may include a roll receiving region 311 in which the first roll member 201 or the second roll member 202 is accommodated. The processing tank 310 may have a bottom wall and side wall providing a space in which the first roll member 201 or the second roll member 202 is accommodated. An inlet or outlet to which a cleaning solution supply line 322, a rinsing solution supply line 332, a discharge line 341, and a circulation line 351 to be described later are connected may be formed on the bottom wall and the side wall of the processing tank 310. The processing tank 310 may be made of a material having acid resistance and corrosion resistance. For example, the processing tank 310 may include an overflow region 312, adjacent to the roll receiving region 311. The overflow region 312 may be separated from the roll receiving region 311 by a partition wall. The overflow region 312 may temporarily store a cleaning solution or a rinsing solution overflowing from the roll receiving region 311.

The cleaning solution supply unit 320 may supply a cleaning solution into the roll receiving region 311. The cleaning solution supply unit 320 may have a cleaning solution supply line 322 having one end connected to a cleaning solution inlet of the processing tank 310. The other end of the cleaning solution supply line 322 may be connected to the cleaning solution supply source 321, and a valve V1 for opening and closing a flow of the cleaning solution may be installed on the cleaning solution supply line 322. The valve V1 may be installed in a position, adjacent to the cleaning solution supply source 321 on the cleaning solution supply line 322.

The rinsing solution supply unit 330 may supply a rinsing solution into the roll receiving region 311. The rinsing solution supply unit 330 may have a rinsing solution supply line 332 having one end connected to a rinsing solution inlet of the processing tank 310. The other end of the rinsing solution supply line 332 may be connected to a rinsing solution supply source 331, and a valve V2 for opening and closing a flow of the rinsing solution may be installed on the rinsing solution supply line 332.

The discharge unit 340 may discharge a cleaning solution or a rinsing solution in the roll receiving region 311 externally of the processing tank 310. The discharge unit 340 may have a discharge line 341 whose one end is connected to an outlet of the processing tank 310. The other end of the discharge line 341 is connected to a drain member 342 such as a pump, and a valve V3 for opening and closing a flow of the discharged cleaning solution or rinsing solution may be installed on the discharge line 341.

The circulation unit 350 may circulate a cleaning solution or the rinsing solution discharged from the processing tank 310 and re-supply the same to the processing tank 310. For example, the circulation unit 350 may supply a cleaning solution or a rinsing solution flowing into the overflow region 312 to the roll receiving region 311. The circulation unit 350 may have a circulation line 351 having one end connected to one side of the processing tank 310, for example, an outlet of the overflow region 312. The other end of the circulation line 351 may be connected to the other side of the processing tank 310, for example, an inlet of the roll receiving region 311. A valve V4 and a pump 353 for opening/closing a flow of the circulating cleaning solution or rinsing solution may be installed on the circulation line 351. The valve V4 and pump 353 may be provided in a larger number than shown in the drawings.

The ultrasonic generating unit 360 may apply ultrasonic vibrations to a cleaning solution or a rinsing solution supplied to the roll receiving region 311. The ultrasonic generating unit 360 may be installed on a bottom wall or a side wall of the processing tank 310. Depending on an example embodiment, the ultrasonic generating unit 360 may be provided in a larger or smaller number than that shown in the drawings. The ultrasonic generating unit 360 may transmit strong vibration due to sound waves to the cleaning solution or the rinsing solution when the first roll member 201 or the second roll member 202 is cleaned, using a piezoelectric body converting electrical energy into physical vibration energy. Accordingly, cavitation bubbles may be ruptured between protrusions P1 and P2 of first and second roll members 201 and 202, and contaminants may be separated from the first and second roll members 201 and 202. The ultrasonic generating unit 360 may generate ultrasonic waves having various frequencies in response to a size of the contaminants. The ultrasonic generating unit 360 may generate ultrasonic waves having a frequency in a range of about 20 kHz to about 1.5 MHz. According to an example embodiment, the ultrasonic generating unit 360 may generate ultrasonic waves having a megasonic frequency in a range of about 700 kHz to about 1.5 MHz. As described above, in the present inventive concept, by introducing the roll cleaning module 300 including the ultrasonic generating unit 360, inverse contamination between the first roll member 201 and the second roll member 202 may be prevented, and cleaning efficiency of the substrate cleaning module 200 may be improved.

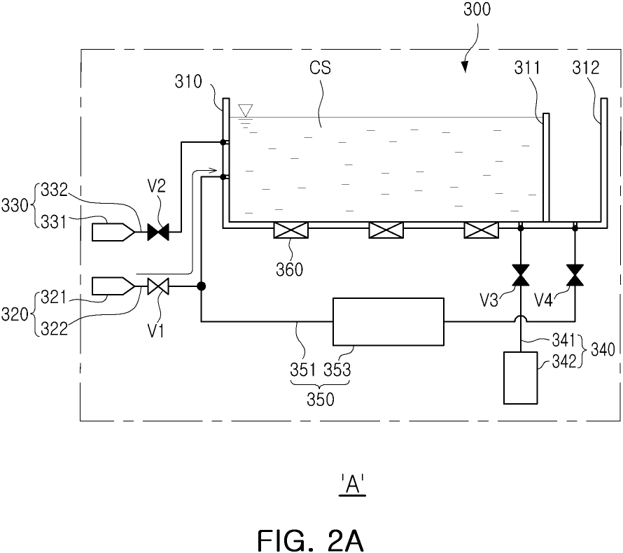

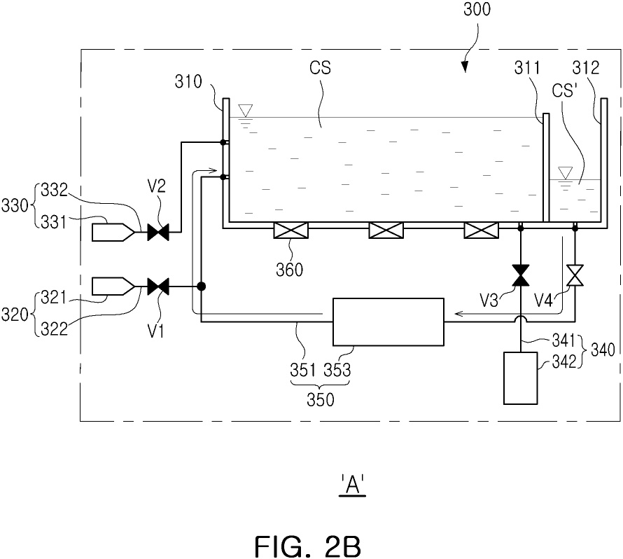

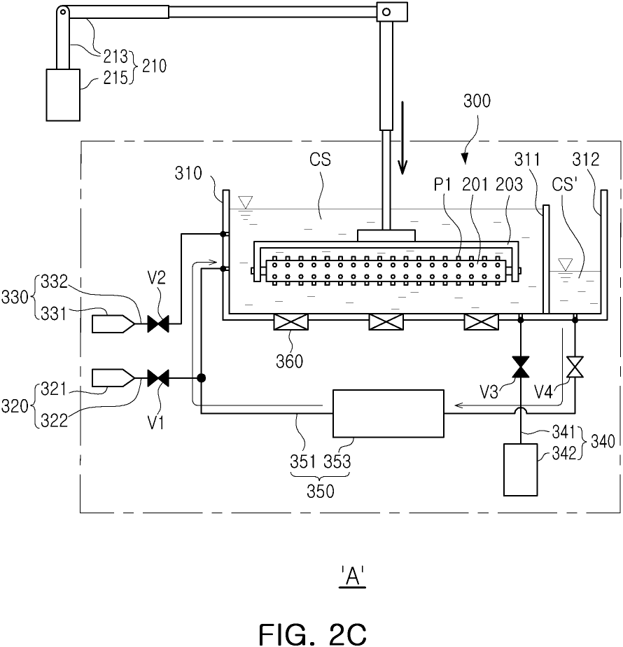

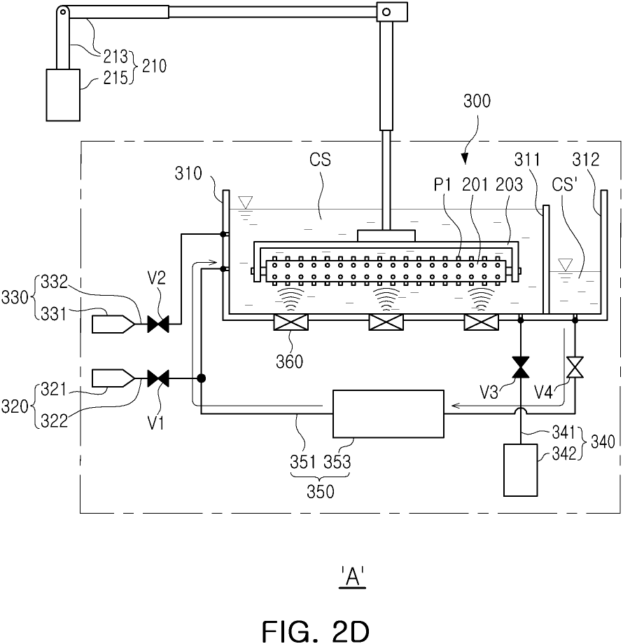

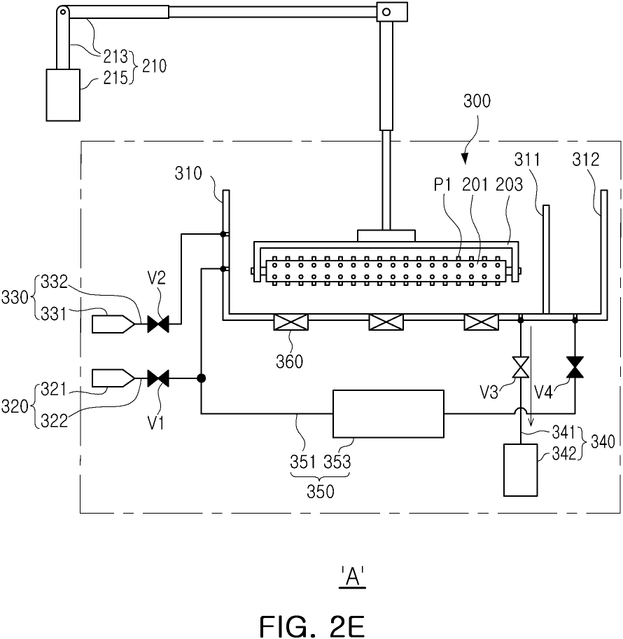

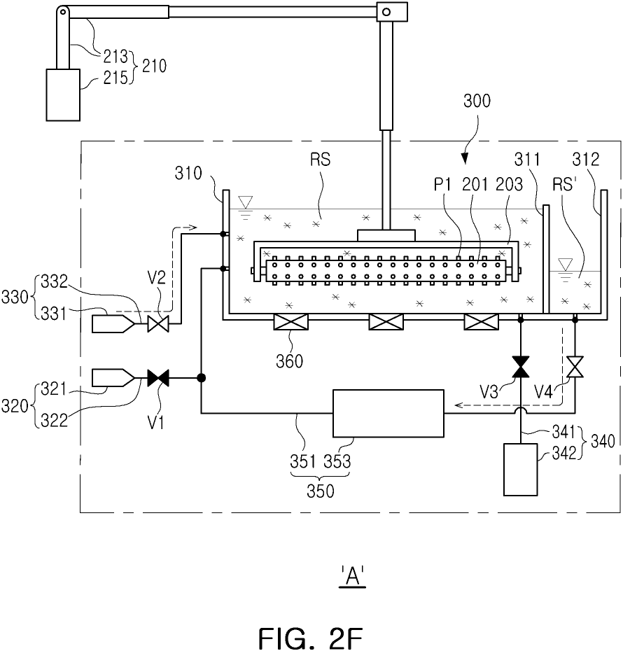

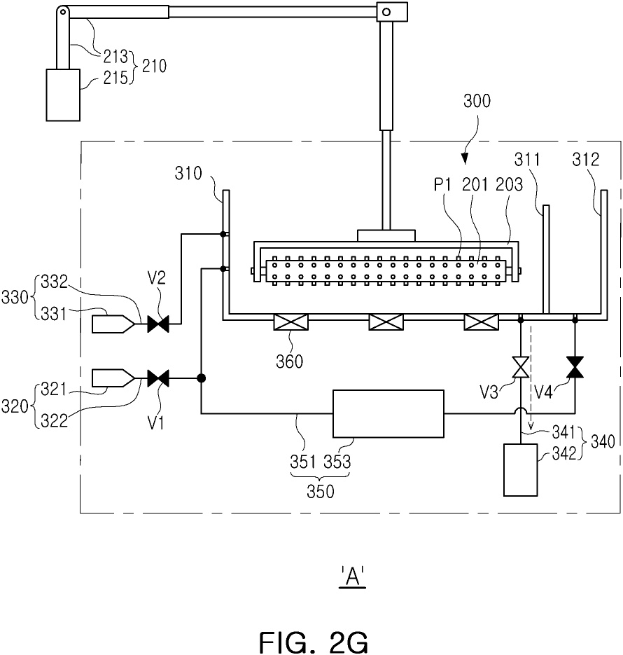

FIGS. 2A to 2G are views illustrating a process of cleaning the first roll member 201 of FIG. 1, according to an example embodiment. FIGS. 2A to 2G are partially enlarged views illustrating region ‘A’ of FIG. 1.

Referring to FIG. 2A, a valve V1 installed on a cleaning solution supply line 322 is opened, and a cleaning solution CS may be supplied from a cleaning solution supply source 321 to a roll receiving region 311 of the processing tank 310. Supply of the cleaning solution CS is continued until the cleaning solution CS reaches a predetermined solution level, or a portion of the cleaning solution C overflows and circulates into an overflow region 312. In this case, a valve V2 installed on a rinsing solution supply line 332, a valve V3 installed on a discharge line 341, and a valve V4 installed on a circulation line 351 are closed. The cleaning liquid CS may include at least one of pure water (DI water), ultrapure water, or hydrofluoric acid (HF), sulfuric acid (H₃SO₄), nitric acid (HNO₃), phosphoric acid (H₃PO₄), standard clean-1 (SC-1) solution, EKC solution, LAL solution, and diluted sulfate peroxide (DSP) solution.

Referring to FIG. 2B, after the cleaning solution CS reaches a predetermined solution level in the roll receiving region 311, supply of the cleaning solution from the cleaning solution supply source 321 to the processing tank 310 may be stopped. In this case, the valve V1 on the cleaning solution supply line 322 may be closed, and the valve V4 on the circulation line 351 may be opened. Accordingly, a portion of cleaning solution CS′ flowing into the overflow region 312 from the roll receiving region 311 may be re-supplied to the roll receiving region 311 through the circulation line 351. This circulation process may be maintained during the cleaning process of the first roll member 201 or the second roll member 202.

Referring to FIG. 2C, a first driving unit 210 may move the first roll member 201 into the roll receiving region 311. For example, a first driving member 215 may transmit driving force to at least one robot arm 213 so that the first roll member 201 is lowered into the processing tank 310 from above the processing tank 310. However, a shape of the first driving unit 210 or a principle of movement of the first roll member 201 is not limited to those illustrated in the drawings. The first driving unit 210 may have various shapes for supporting and moving the first roll member 201.

Referring to FIG. 2D, when the first roll member 201 is immersed in the cleaning solution CS in the roll receiving region 311, foreign objects accumulated between an outer peripheral surface of the first roll member 201 and first protrusions P1 may be removed. In this case, the ultrasonic generating unit 360 may apply ultrasonic vibrations to the cleaning solution CS. The ultrasonic vibrations applied to the cleaning solution CS may promote a chemical reaction between the foreign substance accumulated in the first roll member 201 and the cleaning solution, thereby improving removal efficiency of the foreign substance. For example, the ultrasonic wave may have a frequency in a range of about 700 kHz to about 1.5 MHz. In addition, a first roll holder 203 may rotate the first roll member 201 in the cleaning solution CS. A portion of the cleaning liquid CS′ that overflows during the cleaning process of the first roll member 201 may be re-supplied to the roll receiving region 311 through the circulation line 351.

Referring to FIG. 2E, when a cleaning solution processing of the first roll member 201 is finished, the valve V4 on the circulation line 351 may be closed, and the valve V3 on the discharge line 341 may be opened. The cleaning solution in the roll receiving region 311 may be discharged through the discharge line 341. In addition, a cleaning solution in the overflow region 312 may be re-supplied to the roll receiving region 311 through the circulation line 351, and may be discharged through the discharge line 341. According to an example embodiment, the cleaning solution in the overflow region 312 may be discharged through a separate outlet (not shown) provided in the overflow region 312.

Referring to FIG. 2F, after the cleaning solution in the processing tank 310 is discharged, the rinsing solution RS is supplied to the processing tank 310 to rinse the first roll member 201. When the discharge of the cleaning solution is completed, the valve V3 on the discharge line 341 may be closed, and the valve V2 installed on the rinsing solution supply line 332 may be opened. Accordingly, the rinsing solution RS may be supplied from the rinsing solution source 331 to the processing tank 310. Supply of the rinsing solution RS is continued until the rinsing solution RS reaches a predetermined solution level in the roll receiving region 311, or a portion of the rinsing solution RS′ overflows into the overflow region 312 and circulates. The rinsing solution RS may include pure water (DI water) or ultrapure water. Meanwhile, although not shown in the drawings, an ultrasonic generating unit 360 may apply ultrasonic vibrations to the rinsing solution as shown in FIG. 2D.

In addition, the valve V4 on the circulation line 351 may be opened. Accordingly, a portion of rinsing solution RS′ flowing into the overflow region 312 from the roll receiving region 311 may be re-supplied to the roll receiving region 311 through the circulation line 351. This circulation process may be maintained during the rinsing process of the first roll member 201 or the second roll member 202.

Referring to FIG. 2G, when the rinsing process of the first roll member 201 is finished, the valve V2 on the rinsing solution supply line 332 and the valve V4 on the circulation line 351 may be closed. In addition, the valve V3 on the discharge line 341 may be opened, and the rinsing solution in the processing tank 310 may be discharged to the discharge line 341. According to an example embodiment, a drying process of drying a rinsing solution remaining on a surface of the first roll member 201 may be performed.

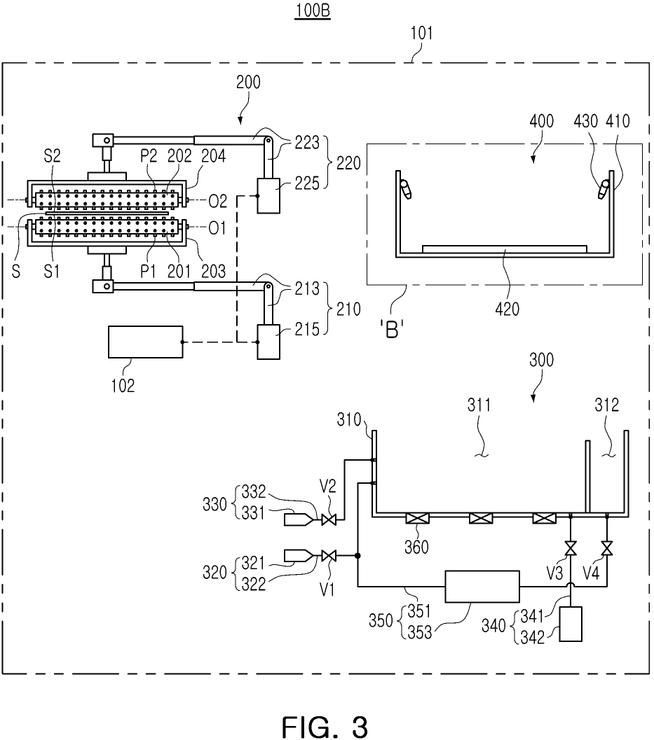

FIG. 3 is a diagram schematically illustrating a configuration of a substrate cleaning device 100B according to an example embodiment of the present inventive concept.

Referring to FIG. 3, the substrate cleaning device 100B according to an example embodiment may have the same or similar characteristics as those described with reference to FIG. 1, except that FIG. 3 includes a first roll cleaning module 300 for cleaning a first roll member 201 and a second roll cleaning module 400 for cleaning a second roll member 202.

The first roll cleaning module 300 may include a processing tank 310, a first cleaning solution supply unit 320, a rinsing solution supply unit 330, a discharge unit 340, a circulation unit 350, and an ultrasonic generating unit 360. Since components of the first roll cleaning module 300 have substantially the same characteristics as those described with reference to FIG. 1, overlapping descriptions thereof will be omitted.

The second roll cleaning module 400 may include a housing 410, a brush pad 420, and a second cleaning solution supply unit 430. The housing 410 may provide a space in which the second roll member 202 is accommodated.

The brush pad 420 may be disposed in the housing 410. Since the second roll member 202 is seated on the brush pad 420 for cleaning the second roll member 202, the brush pad 420 may be made of a material that does not damage the second roll member 202. For example, the brush pad 420 may include a pad portion including a material with strong durability against pure water (DI water) and a brush portion including a nylon-based or polymer-based material.

The second cleaning solution supply unit 430 may supply a second cleaning solution to the brush pad 420 on which the second roll member 202 is seated. The second cleaning solution may include at least one of pure water (DI water), ultrapure water, or hydrofluoric acid (HF), sulfuric acid (H3SO4), nitric acid (HNO3), phosphoric acid (H3PO4), standard clean-1 (SC-1) solution, EKC solution, LAL solution, and diluted sulfate peroxide (DSP) solution.

In the present example embodiment, the control unit 102 may be configured to control the first driving unit 210 such that the first roll member 201 is in contact with the lower surface S1 of the substrate S or is accommodated in a roll receiving region 311 of the processing tank 310, and control the second driving unit 220 such that the second roll member 202 is in contact with the upper surface S2 of the substrate S or is seated on the brush pad 420 in the housing 410. The control unit 102 may be a computer (or several interconnected computers) and can include, for example, one or more processors configured by software, such as a central processing unit (CPU), a graphic processing unit (GPU), etc. In the present example embodiment, the first roll cleaning member 300 and the second roll cleaning member 400 are configured to clean the first and second roll members 201 and 202 in different manners, but the present inventive concept is not limited thereto. According to an example embodiment, the second roll cleaning module 400 may be replaced with an ultrasonic cleaning module such as the first roll cleaning module 300.

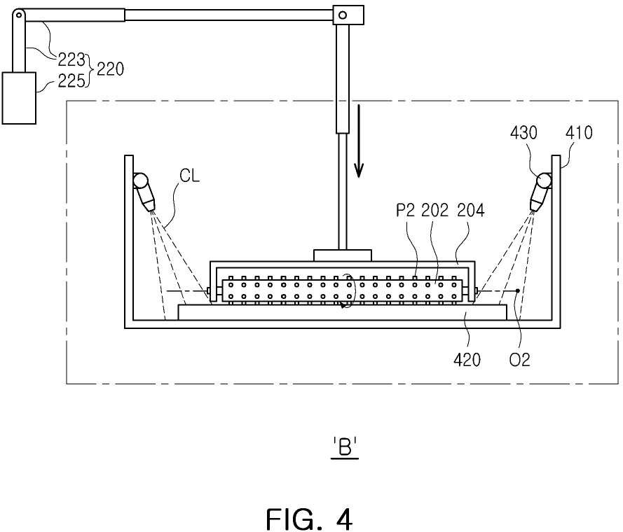

FIG. 4 is a diagram illustrating a process of cleaning the second roll member 202 of FIG. 3. FIG. 4 is a partially enlarged view illustrating region ‘B’ of FIG. 3.

Referring to FIG. 4, the second driving unit 220 may move a second roll member 202 into the housing 410. For example, the second driving member 225 may transmit driving force to the at least one robot arm 223 so that the second roll member 202 is lowered into the housing 410 from above the housing 410. However, a shape of the second driving unit 220 or a principle of movement of the second roll member 202 is not limited to those shown in the drawings. The second driving unit 220 may have various shapes for supporting and moving the second roll member 202. As the second roll member 202 rotates while being seated on a brush pad 420, foreign objects attached to the second roll member 202 may be removed. The second roll member 202 may have a rotation shaft O2, parallel to an upper surface of the brush pad 420. A second cleaning solution supply unit 430 may improve cleaning efficiency of the second roll member 202 by spraying a second cleaning solution CL onto the brush pad 420.

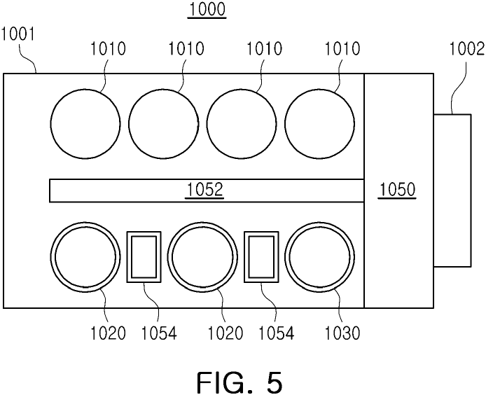

FIG. 5 is a diagram illustrating an example of a substrate processing device 1000 to which the substrate cleaning device according to the present inventive concept is introduced.

Referring to FIG. 5, the substrate processing device 1000 includes a housing 1001 having a substantially rectangular shape and a load port 1002 in which a substrate cassette for stocking a plurality of substrates such as semiconductor wafers, or the like are loaded. The load port 1002 is disposed adjacent to the housing 1001. The load port 1002 may be equipped with an open cassette, a Standard Manufacturing Interface (SMIF) pod, or a Front Opening Unified Pod (FOUP). SMIF and FOUP are airtight containers capable of maintaining an environment independent of an external space by accommodating the substrate cassette therein and covering the same with a partition.

A plurality of polishing devices 1010 (four in this example), at least one substrate cleaning device 1020 (two in this example) for cleaning the substrate after polishing, and a substrate drying device 1030 for drying the substrate after cleaning are accommodated inside a housing 1001. The polishing device 1010 is arranged along a longitudinal direction of the substrate processing device 1000, and the substrate cleaning device 1020 and the substrate drying device 1030 are also arranged along the longitudinal direction of the substrate processing device 1000. The substrate cleaning devices 100A and 100B of FIGS. 1 and 3 may be applied to at least one substrate cleaning device 1020.

A substrate transfer robot 1050 may be disposed inside the housing 1001 adjacent to the load port 1002. A substrate return robot 1052 may be disposed parallel to an arrangement direction of the polishing device 1010. The substrate transfer robot 1050 may receive a substrate before polishing from the load port 1002 and deliver the same to the substrate return robot 1052, and receive a substrate after drying from the substrate drying device 1030 and return the same to the load port 1002. The substrate return robot 1052 transfers the substrate received from the substrate transfer robot 1050, and transfers the substrate between the polishing devices 1010.

In addition, the at least one substrate cleaning device 1020 may be disposed as a first substrate cleaning device 1020 (left side) and a second substrate cleaning device 1020 (right side) arranged in parallel. For example, a second substrate transfer robot 1052 for transferring the cleaned substrate may be disposed between the first substrate cleaning device 1020 (left side) and the second substrate cleaning device 1020 (right side) and between the second substrate cleaning device 1020 (right side) and the substrate drying device 1030.

FIG. 6A is a perspective view schematically illustrating a use state of a substrate cleaning module of a substrate cleaning device 1020 provided in the substrate processing device of FIG. 5, and FIG. 6B is a cross-sectional view illustrating a section of region ‘C’ of FIG. 6A.

Referring to FIGS. 6A and 6B, the substrate cleaning device 1020 may include an upper roll member (a second roll member) 202 that is rotatably supported by an upper roll holder (not shown), and a lower roll member (a first roll member) 201 that is rotatably supported by a roll holder (not shown). each of the upper roll member 202 and the lower roll member 201 may have a cylindrical shape, may extend in an elongated shape, and may include, for example, PVA. In addition, the upper roll member 202 may be configured to be raised and lowered with respect to an upper surface of the substrate S, and the lower roll member 201 may be configured to be raised and lowered with respect to a lower surface of the substrate S. For example, although not illustrated, an upper driving member (e.g., the first driving member 215 of FIGS. 1 and 3) may apply a driving force to an upper robot arm (e.g., the first robot arm 213 of FIGS. 1 and 3) so that the upper roll member 201 is raised and lowered with respect to the upper surface of the substrate S, and a lower driving member (e.g., the second driving member 225 of FIGS. 1 and 3) may apply a driving force to a lower robot arm (e.g., the second robot arm 223 of FIGS. 1 and 3) so that the lower roll member 202 is raised and lowered with respect to the lower surface of the substrate S.

The upper roll member 202 may rotate in a first direction F1 by a rotation driving means, and the lower roll member 201 may rotate in a second direction F2 by a rotation driving means. The rotation driving means may be a rotation driving motor that causes the upper and lower roll member 202 and 201 to rotate. An upper cleaning solution supply nozzle 1032 for supplying a cleaning solution to an upper surface of the substrate S may be disposed above the substrate S. The substrate S may be supported and rotated by spindles 1021. For example, the spindles 1021 may cause the substrate S to rotate about a central rotation shaft (i.e., rotational center) OS of the substrate S. A lower cleaning solution supply nozzle 1031 for supplying a cleaning solution to a lower surface of the substrate S may be disposed below the substrate S. The lower cleaning solution supply nozzle 1031 and the upper cleaning solution supply nozzle 1032 may supply a cleaning solution or a rinsing solution to the lower surface and the upper surface of the substrate S, respectively.

The substrate cleaning device 1020 is a rotation mechanism of the substrate S, and may further include a plurality of spindles 1021 disposed adjacent to an edge of the substrate S to support a peripheral portion of the substrate S and horizontally rotate the substrate S. The plurality of spindles 1021 (four in FIG. 6A) (substrate holding support means) may be configured to be movable in a horizontal direction.

The substrate cleaning device 1020 may dispose the peripheral portion of the substrate S in a fitting groove formed on an outer peripheral side surface of a coma 1021a installed above the spindle 1021, press the same thereinside, and rotates the coma 1021a, to horizontally rotate the substrate S. For example, two coma 1021a among the four coma 1021a may apply rotational force to the substrate S, and the other two coma 1021a may act as a bearing that receives rotation of the substrate S. According to an example embodiment, all of the coma 1021a may be connected to the driving mechanism to apply rotational force to the substrate S.

In a state in which the substrate S is horizontally rotated, a cleaning solution and a rinsing solution may be supplied from the lower cleaning solution supply nozzle 1031 and the upper cleaning solution supply nozzle 1032. In addition, by rotating and lowering the upper roll member 202 to contact an upper surface of the rotating substrate S, and rotating and lowering the lower roll member 201 to contact a lower surface of the rotating substrate S, the upper and lower surfaces of the substrate S may be scrub-cleaned.

Both lengths of the upper roll member 202 and the lower roll member 201 are both set longer than a diameter of the substrate S. A rotation shaft of each of the lower roll member 201 and the upper roll member 202, for example, a first rotation shaft O1 and a second rotation shaft O2, respectively, may extend to cover an entire diameter of the substrate S, while being substantially orthogonal to, a central rotation shaft (i.e., rotational center) OS of the substrate S. Accordingly, an entire area of the lower surface and the upper surface of the substrate S may be simultaneously cleaned by the lower roll member 201 and the upper roll member 202, respectively.

As illustrated in FIG. 6B, when the upper roll member 202 and the lower roll member 201 are in direct contact with the substrate S, at least a portion of first protrusions P1 and at least a portion of second protrusions P2 may be in contact with each other in a region in which the upper and lower roll members 202 and 201 do not overlap the substrate S. This may cause reverse contamination in which foreign objects move from the lower roll member 201 to the upper roll member 202 or from the upper roll member 202 to the lower roll member 201. In the present inventive concept, by introducing a roll cleaning module for removing foreign objects attached to the lower roll member 201 and the upper roll member 202 after cleaning the substrate S, a cleaning effect of the substrate cleaning device 1020 may be improved.

As set forth above, according to example embodiments of the present inventive concept, by introducing a roll cleaning module for removing particles attached to a substrate cleaning roll member, a substrate cleaning device having improved cleaning ability and a substrate cleaning method using the same may be provided.

While example embodiments have been shown and described above, it will be apparent to those skilled in the art that modifications and variations could be made without departing from the scope of the present inventive concept as defined by the appended claims. Accordingly, various types of substitution, modification and change will be possible by those skilled in the art within the scope not departing from the technical spirit of the present inventive concept described in the claims, and this also falls within the scope of the present inventive concept.

1. A substrate cleaning device, comprising:
a substrate cleaning module including a first roll member disposed adjacent to a lower surface of a substrate, a first driving unit configured to move the first roll member in vertical and horizontal directions with respect to the lower surface of the substrate, a second roll member disposed adjacent to an upper surface of the substrate, and a second driving unit configured to move the second roll member in vertical and horizontal directions with respect to the upper surface of the substrate;
a first roll cleaning module including a processing tank including a roll receiving region having the first roll member accommodated therein, a first cleaning solution supply unit configured to supply a first cleaning solution to the roll receiving region, and an ultrasonic generating unit configured to apply ultrasonic vibrations to the first cleaning solution supplied to the roll receiving region;
a second roll cleaning module including a housing having the second roll member accommodated therein, a brush pad disposed in the housing and on which the second roll member is seated, and a second cleaning solution supply unit configured to supply a second cleaning solution to the brush pad on which the second roll member is seated; and
a control unit configured to control the first driving unit so that the first roll member is in contact with the lower surface of the substrate or is accommodated in the roll receiving region of the processing tank, and to control the second driving unit so that the second roll member is in contact with the upper surface of the substrate or is seated on the brush pad in the housing.

2. The substrate cleaning device of claim 1, wherein the substrate cleaning module further comprises a first roll holder configured to rotate the first roll member and a second roll holder configured to rotate the second roll member.

3. The substrate cleaning device of claim 2,
wherein a first rotation shaft of the first roll member is parallel to the lower surface of the substrate, and
wherein a second rotation shaft of the second roll member is parallel to the upper surface of the substrate.

4. The substrate cleaning device of claim 1,
wherein the first roll member has a cylindrical shape having first protrusions on an outer circumferential surface thereof, and
wherein the second roll member has a cylindrical shape having second protrusions on an outer circumferential surface thereof.

5. The substrate cleaning device of claim 4, wherein, when the first and second roll members are in contact with the substrate, at least a portion of the first protrusions and at least a portion of the second protrusions are in contact with each other in a region in which the substrate and the first and second roll members do not overlap.

6. The substrate cleaning device of claim 1, wherein each of the first and second roll members extend to be parallel to the lower surface and the upper surface of the substrate, respectively, and have a length greater than a diameter of the substrate.

7. The substrate cleaning device of claim 1, wherein the first and second driving units comprise at least one robot arm and at least one driving member transmitting driving force to the at least one robot arm, respectively.

8. The substrate cleaning device of claim 1,
wherein the ultrasonic generating unit applies the ultrasonic vibrations by generating ultrasonic waves, and
wherein the ultrasonic waves have a frequency in a range of about 700 kHz to about 1.5 MHz.

9. The substrate cleaning device of claim 1, wherein the processing tank further includes an overflow region adjacent to the roll receiving region.

10. The substrate cleaning device of claim 9, wherein the first roll cleaning module further includes a cleaning solution circulation unit configured to supply at least a portion of the first cleaning solution flowing into the overflow region to the roll receiving region.

11. The substrate cleaning device of claim 1, wherein the first roll cleaning module further includes a discharge unit configured to discharge the first cleaning solution in the roll receiving region.

12. The substrate cleaning device of claim 1, wherein the first roll cleaning module further includes a rinsing solution supply unit configured to supply a rinsing solution into the roll receiving region.

13. The substrate cleaning device of claim 12, wherein the rinsing solution comprises pure water or ultrapure water.

14. The substrate cleaning device of claim 1, wherein the first and second cleaning solutions comprise at least one of pure water, ultrapure water, hydrofluoric acid (HF), sulfuric acid (H₃SO₄), nitric acid (HNO₃), phosphoric acid (H₃PO₄), a standard clean-1 (SC-1) solution, an EKC solution, a LAL solution, and a diluted sulfate peroxide (DSP) solution.

15. The substrate cleaning device of claim 1,
wherein the substrate cleaning module further includes a spindle disposed adjacent to an edge of the substrate, and
wherein the spindle is configured to horizontally rotate the substrate.

16. The substrate cleaning device of claim 1, wherein the substrate cleaning module further includes a cleaning solution supply nozzle configured to supply a third cleaning solution to the lower surface or the upper surface of the substrate.

17. A substrate cleaning device, comprising:
a substrate cleaning module including a first roll member disposed adjacent to a lower surface of a substrate, a first driving unit configured to move the first roll member in vertical and horizontal directions with respect to the lower surface of the substrate, a second roll member disposed adjacent to an upper surface of the substrate, and a second driving unit configured to move the second roll member in vertical and horizontal directions with respect to the upper surface of the substrate;
a roll cleaning module including a processing tank including a roll receiving region having the first roll member or the second roll member accommodated therein, a cleaning solution supply unit configured to supply a cleaning solution to the roll receiving region, and an ultrasonic generating unit configured to apply ultrasonic vibrations to the cleaning solution supplied to the roll receiving region; and
a control unit configured to control the first and second driving units so that the first roll member and the second roll member are in contact with the lower surface and the upper surface of the substrate, respectively, or are accommodated in the roll receiving region of the processing tank.

18. A substrate cleaning device, comprising:
a substrate cleaning module including a first roll member having first protrusions, and disposed adjacent to a lower surface of a substrate, a first driving unit configured to move the first roll member in vertical and horizontal directions with respect to the lower surface of the substrate, and a second roll member having second protrusions and disposed adjacent to an upper surface of the substrate, and a second driving unit configured to move the second roll member in vertical and horizontal directions with respect to the upper surface of the substrate;
a first roll cleaning module including a processing tank including a roll receiving region having the first roll member accommodated therein, a first cleaning solution supply unit configured to supply a first cleaning solution to the roll receiving region, and an ultrasonic generating unit configured to apply ultrasonic vibrations to the first cleaning solution supplied to the roll receiving region; and
a control unit configured to control the first driving unit so that the first roll member is in contact with the lower surface of the substrate or is accommodated in the roll receiving region of the processing tank,
wherein, when each of the first roll member and the second roll member is in contact with the lower surface and the upper surface of the substrate, at least a portion of the first protrusions and at least a portion of the second protrusions are in contact with each other.

19. The substrate cleaning device of claim 18, further comprising:
a second roll cleaning module including a housing having the second roll member accommodated therein, a brush pad disposed in the housing and on which the second roll member is seated, and a second cleaning solution supply unit configured to supply a second cleaning solution to the brush pad on which the second roll member is seated.

20. The substrate cleaning device of claim 19, wherein the control unit is configured to control the second driving unit such that the second roll member is in contact with the upper surface of the substrate or is seated on the brush pad in the housing.

21-23. (canceled)
